(19) United States
(12) Patent Application Publication
(10) Pub. No.: US 2009/0175468 A1
(43) Pub. Date: Jul. 9, 2009

(54) METHODS FOR PREVENTING UNWANTED SOUND CAUSED BY GAIN CHANGES

(75) Inventors: Yiou-Wen Cheng, Taipei County (TW); Hsi-Wen Nien, Hsinchu County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 11/971,335

(22) Filed: Jan. 9, 2008

(51) Int. Cl. H03G 3/20

(52) U.S. Cl. 381/107

(57) ABSTRACT

An electronic device capable of preventing unwanted sound caused by gain changes are provided. An amplifier thereof amplifies an input signal and generates a amplified signal. An analog-to-digital converter (ADC) thereof converts the amplified signal to a digital signal. An automatic gain controller (AGC) thereof updates a gain of the amplifier according to a strength of the amplified signal or amplified digital signal. A smoothing unit thereof updates a gain of the digital signal from the ADC before and/or after the AGC updates the gain of the amplifier, such that click-and-pop caused when the AGC updates the gain of the amplifier is eliminated.

### BACKGROUND OF THE INVENTION

1. Field of the Invention

The invention relates to audio processing, and in particular to methods for preventing click-and-pop caused by gain changes and an electronic device using the same.

2. Description of the Related Art

Many electrical devices, such as telephone devices, mobile phones or signal transceivers, including digital cordless telephone base stations and digital telephone answering machines, receive an input signal wherein the input signal gain or strength can vary widely and rapidly. In such cases, in the presence of relatively large fluctuations in input signal levels, it is often desirable to maintain the gain of the input signal within an acceptable range. This is particularly desirable if the input signal is provided to another device requiring the input signal level to be within a certain range. Automatic gain controllers (AGCs) are commonly included in such electrical devices to maintain the gain of the input signal at a relatively constant value or within a desired dynamic range by adjusting the amplification of the input signal in inverse proportion to the input signal strength.

### BRIEF SUMMARY OF THE INVENTION

Embodiments of an electronic device are provided. An amplifier thereof amplifies an input signal and generates an amplified signal. An analog-to-digital converter (ADC) thereof converts the amplified signal to a digital signal. An automatic gain controller (AGC) thereof updates a gain of the amplifier according to a strength of the amplified signal or amplified digital signal. A smoothing unit thereof updates a gain of the digital signal from the ADC before and/or after the AGC updates the gain of the amplifier, such that click-and-pop caused when the AGC updates the gain of the amplifier is eliminated.

The invention provides an embodiment of a method for preventing click-and-pop caused by gain changes, in which an input signal is amplified by an amplifier, and the amplified input signal is converted to a digital signal. A gain of the amplifier is updated according to a strength of the amplified signal or amplified digital signal, and a gain of the digital signal is updated before and/or after updating the gain of the amplifier.

### BRIEF DESCRIPTION OF THE DRAWINGS

The invention can be more fully understood by reading the subsequent detailed description and examples with references made to the accompanying drawings, wherein:

FIG. 1 shows a diagram of an embodiment of an electronic device according to the invention;

FIG. 2 shows a diagram illustrating signals being amplified step by step when the gain of a programmable gain amplifier (PGA) is increased according to an embodiment of the invention;

FIG. 3 shows a diagram of an embodiment of an electronic device according to the invention;

FIG. 4 shows a diagram of an embodiment of an electronic device according to the invention;

FIG. 5A shows a diagram illustrating gain smoothing of signals from the analog-to-digital converter (ADC) by a post-smoothing unit according to an embodiment of the invention;

FIG. 5B shows a diagram illustrating gain smoothing of signals from the ADC by a post-smoothing unit according to an embodiment of the invention;

FIG. 6 shows another embodiment of the electronic device according to the invention;

FIG. 7 shows an embodiment of a post-smoothing unit according to the invention;

FIG. 8 shows an embodiment of an electronic device according to the invention;

FIG. 9A shows a diagram illustrating gain smoothing of signals from the ADC by a pre-smoothing unit according to an embodiment of the invention;

FIG. 9B shows a diagram illustrating gain smoothing of signals from the ADC by a pre-smoothing unit according to an embodiment of the invention;

FIG. 10 shows an embodiment of an electronic device according to the invention;

FIG. 11 shows an embodiment of a pre-smoothing unit according to the invention;

FIG. 12 shows an embodiment of an electronic device according to the invention;

FIG. 13A shows a diagram illustrating gain smoothing of signals from the ADC by a mix-smoothing unit according to an embodiment of the invention;

FIG. 13B shows a diagram illustrating gain smoothing of signals from the ADC by a mix-smoothing unit according to an embodiment of the invention;

FIG. 14 shows an embodiment of an electronic device according to the invention; and

FIG. 15 shows an embodiment of a mix-smoothing unit according to the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

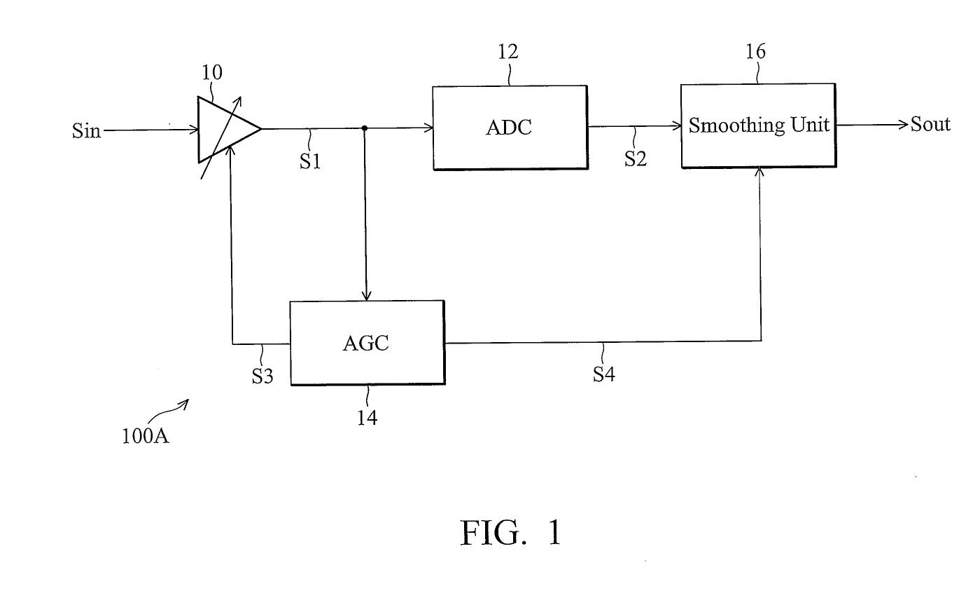

FIG. 1 shows a diagram of an embodiment of an electronic device according to the invention. As shown, the electronic device 100A can be a telephone device, a mobile phone or a signal transceiver, including digital cordless telephone base stations and digital telephone answering machines, but is not limited thereto. For example, in digital telephone transceivers, an analog input, such as speech, music or dual-tone multi-frequency (DTMF) signals, is converted to a digital signal by an analog-to-digital converter. A digital signal processor (DSP) or other digital circuitry in the telephone device then performs operations on the digital signal. For example, the telephone answering device typically includes a vocoder which performs voice coding on the digital signal and stores the coded data.

The electronic device 100A comprises a programmable gain amplifier (PGA) 10, an analog-to-digital converter (ADC) 12, an automatic gain controller (AGC) 14 and a smoothing unit 16. The PGA 10 has an adjustable gain which is controlled by a signal S3, and the amplifier 10 amplifies or attenuates input signals Sin and generates corresponding amplified signals S1. Namely, the PGA 10 receives the input signals Sin, amplifies the received input signals Sin according to the control of the AGC 14, and then outputs the amplified signals S1 to the ADC 12. The ADC 12 converts the amplified signals S1 from the PGA 10 to digital signals S2.

The AGC 14 maintains the gain of the input signal Sin at a relatively constant value or within a desired dynamic range by adjusting the amplification of the input signal Sin in inverse proportion to the input signal strength. For example, the AGC 14 examines and analyzes strength of the amplified signal S1 (analog signals) and outputs a signal S3 to adjust the gain of the PGA 10, thereby avoiding from a loss of information caused by distortion (including clipping) or low signal to noise ratio (SNR). The AGC 14 selectively increases the gain, decreases the gain or does not change the gain of the PGA 10 according to the analysis of the signal S1. The AGC 14 is preferably a digital signal processor (DSP) programmed to perform the device functions. The AGC 14 may also be comprised of a programmed general purpose CPU or dedicated digital or analog circuit.

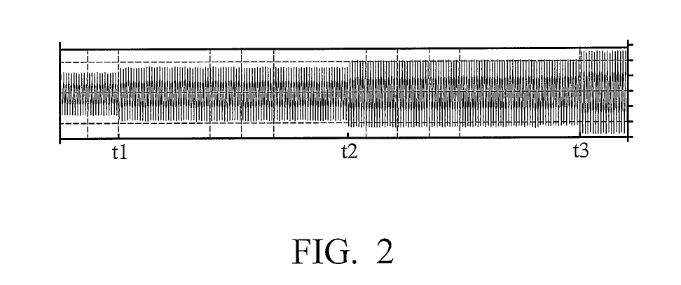

However, click-and-pop may occur when the AGC 14 is turned on to adjust the PGA 10. Because the gain step is discontinuous, click-and-pop may occur across the gain change boundary. For example, as shown in FIG. 2, the signal S1 is amplified step by step when the gain of the PGA 10 is increased step by step, and click-and-pop occurs at times t1, t2 and t3 (i.e., the transients or the moments that the gain of the PGA 10 changes). Further, the finer the gain step, the larger the area of the PGA 10. Unfortunately, click-and-pop still occurs when the gain of the PGA 10 changes because the gain step is still present, even if the gain step of the PGA 10 is fine gain step.

In order to overcome such a problem, the smoothing unit 16 smoothes the gain step when the gain of the PGA 10 changes according to control of the AGC 14 and then outputs the smoothed signal serving as an output signal Sout. In this case, the smoothing unit 16 is coupled between the ADC 12 and the AGC 14, and generates a smooth gain to adjust the (digital) signal S2 from the ADC 12 according to a signal S4 from the AGC 14, thereby smoothing the gain step of the PGA 10 such that click-and-pop can be eliminated. For example, the smoothing unit 16 can be a pre-smoothing unit to smooth the gain step of the PGA 10 before the AGC 14 updates gain of the PGA 10, a post-smoothing unit to smooth the gain step of the PGA 10 when the AGC 14 updates gain of the PGA 10 or a combination thereof. An application circuit (not shown), such as a digital telephone answering machine, preferably receives and processes the output signal Sout to perform a desired function. Detailed description of the smoothing unit 16 is provided later, and only briefly described herein.

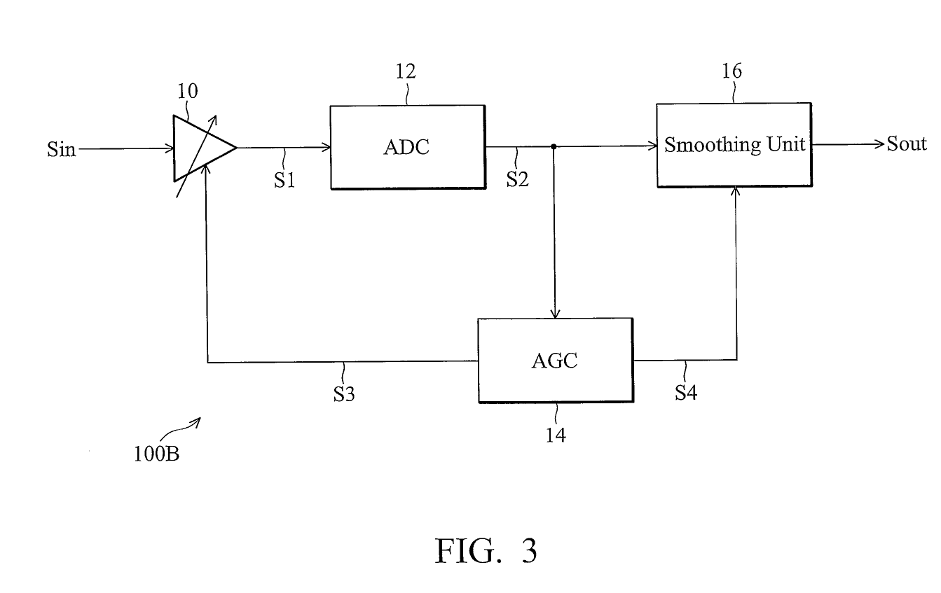

FIG. 3 shows a diagram of an embodiment of an electronic device according to the invention. As shown, the electronic device 100B is similar to the electronic device 100A shown in FIG. 1, differing in that the AGC 14 generates the signals S3 and S4 to control the PGA 10 and the smoothing unit 16 according to the signals S2 (digital signals) generated by the ADC 12 rather than the signals S1 (analog signals) generated by the PGA 10. The structure and operations of the electronic device 100B which are same as that in electronic device 100A are omitted for brevity.

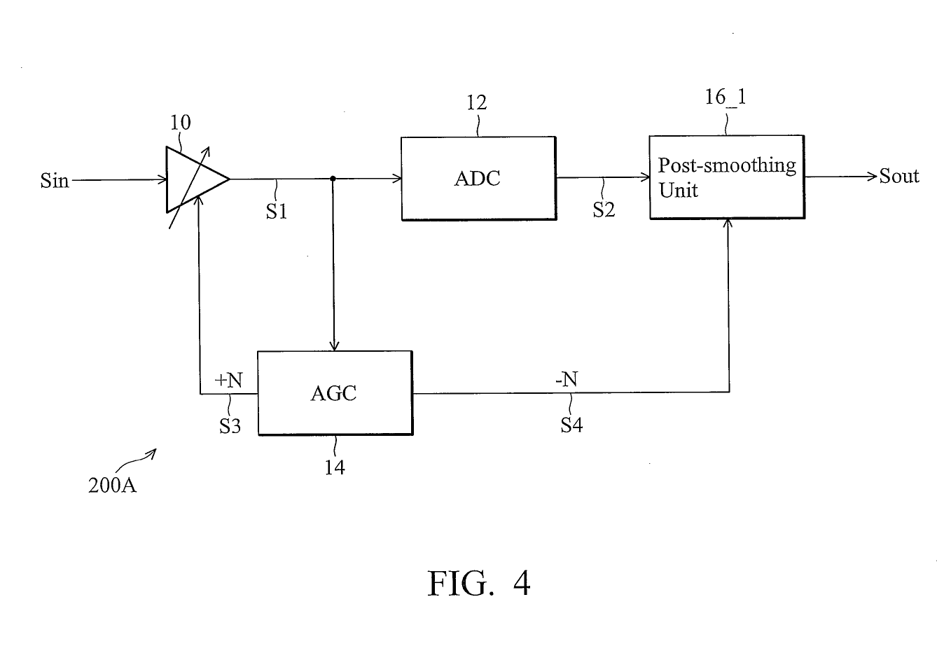

FIG. 4 is a diagram of an embodiment of an electronic device according to the invention. As shown, in the electronic device 200A, the post-smoothing unit generates a smooth gain to update the signals S2 during a time period that the AGC updates gain of the PGA 10, such that the gain change of the signals S2 (amplified by the PGA 10 and converted by the ADC 12) can be smoothed.

When the AGC 14 generates the signals S3 to update the gain of the PGA 10 by +N dB according to signal strength of the signals S1, the AGC 14 also generates the signals S4 to enable the post-smoothing unit 16_1 to update (decrease) the gain of the signals S2 from ADC 12 during a time period after the gain of the PGA 10 changes, such that gain change of the output signals Sout can be smoothed.

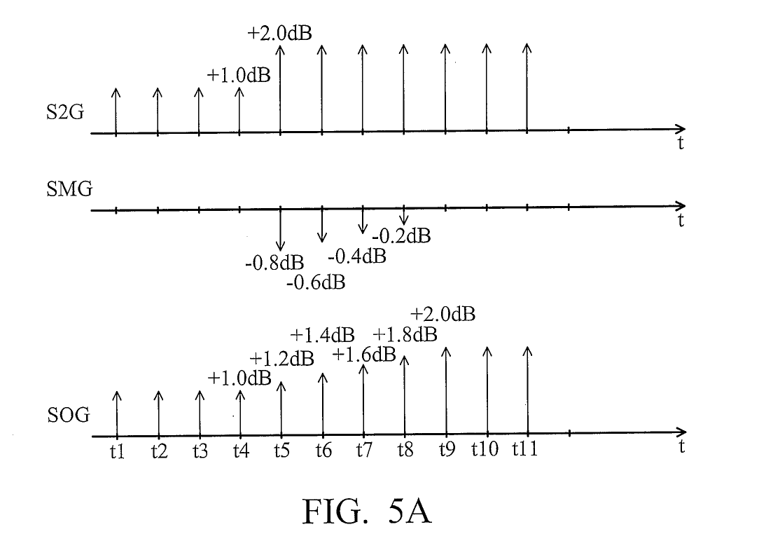

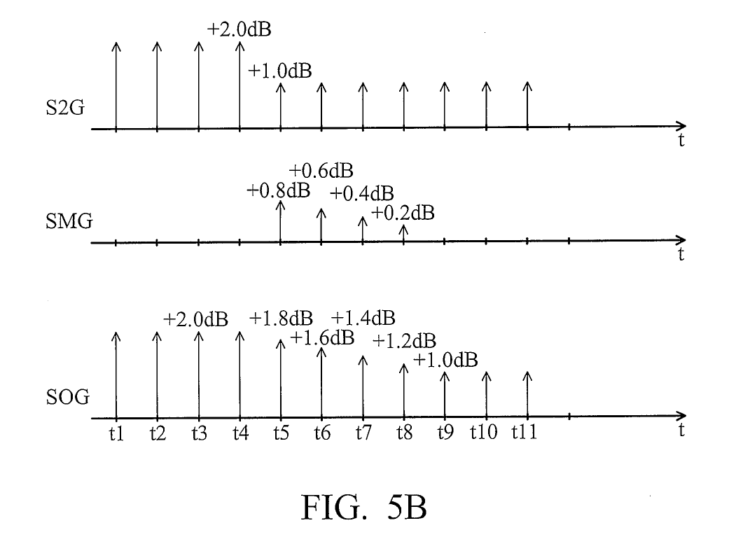

FIG. 5A shows a diagram illustrating gain smoothing of signals from the ADC by the post-smoothing unit according to an embodiment of the invention, in which S2G represents gain of the signals S2 from the ADC 12, SMG represents the smooth gain generated by the post-smoothing unit 16, and the SOG represents gain of the output signals Sout. As shown, the gain S2G of +1 dB of the signals S2 is updated (increased) with +2 dB (i.e. is increased by 1 dB) when the AGC 14 updates gain of the PGA 10 with +1 dB at time t5. Concurrently, the post-smoothing unit 16_1 generates the smooth gain SMG with −0.8 dB to adjust the gain S2G (i.e., +2 dB), such that the gain SOG of the output signal Sout is only increased to +1.2 dB from +1.0 dB at time t5.

At time t6, the post-smoothing unit 16_1 then generates the smooth gain SMG with −0.6 dB to adjust the gain S2G (i.e., +2 dB), such that the gain SOG is increased to +1.4 dB from +1.2 dB. At time t7, the post-smoothing unit 16_1 generates the smooth gain SMG with −0.4 dB to adjust the gain S2G (i.e., +2 dB), such that the gain SOG is increased to +1.6 dB from +1.4 dB. At time t8, the post-smoothing unit 16_1 then generates the smooth gain SMG with −0.2 dB to adjust the gain S2G (i.e., +2 dB), such that the gain SOG is increased to +1.8 dB from +1.6 dB. Finally, after time t9, the post-smoothing unit 16_1 generates the smooth gain SMG with 0 dB to adjust the gain S2G, i.e., the post-smoothing unit 16_1 stops adjusting the gain S2G of the signals S2, such that the gain SOG of the output signals Sout is increased to +2.0 dB from +1.8 dB.

In this case, the smooth gain generated by the post-smoothing unit 16_1 is adjusted to 0 dB from −0.8 dB gradually, but is not limited thereto. The smooth gain generated by the post-smoothing unit 16_1 can also be adjusted to 0 dB from −N dB gradually when the gain S2G of the signals S2 is updated with +N dB resulting from that the AGC 14 updates gain of the PGA 10 with +N dB.

When the AGC 14 generates the signals S3 to update the gain of the PGA 10 with −N dB according to signal strength of the signals S1, the AGC 14 also generates the signals S4 to enable the post-smoothing unit 16_1 to update the gain of the signals S2 from ADC 12 during a time period after the moments (or transients) of the gain of the PGA 10 changes, such that gain change of the output signals Sout can be smoothed.

FIG. 5B shows a diagram illustrating gain smoothing of the signals from the ADC by the post-smoothing unit according to an embodiment of the invention. As shown, the gain S2G of the signal S2 is adjusted to +1 dB from +2 dB as the AGC 14 updates gain of the PGA 10 with −1 dB at time t5. Concurrently, the post-smoothing unit 16_1 generates the smooth gain SMG with +0.8 dB to adjust the gain S2G (i.e., +1 dB), such that the gain SOG of the output signals Sout is only decreased to +1.8 dB from +2.0 dB at time t5.

At time t6, the post-smoothing unit 16_1 then generates the smooth gain SMG with +0.6 dB to adjust the gain S2G (i.e., +1.0 dB), such that the gain SOG is decreased to +1.6 dB from +1.8 dB. At time t7, the post-smoothing unit 16_1 generates the smooth gain SMG with +0.4 dB to adjust the gain S2G (i.e., +1.0 dB), such that the gain SOG is decreased to +1.4 dB from +1.6 dB. At time t8, the post-smoothing unit 16_1 then generates the smooth gain SMG with +0.2 dB to adjust the gain S2G (i.e., +1.0 dB), such that the gain SOG is decreased to +1.2 dB from +1.4 dB. Finally, after time t9, the post-smoothing unit 16_1 generates the smooth gain SMG with 0 dB to adjust the gain S2G, i.e., the post-smoothing unit 16_1 stops adjusting the gain S2G of the signal S2, such that the gain SOG of the output signal Sout is decreased to +1.0 dB from +1.2 dB.

In this case, the smooth gain generated by the post-smoothing unit 16_1 is adjusted to 0 dB from +0.8 dB gradually, but is not limited thereto. The smooth gain generated by the post-smoothing unit 16_1 can also be adjusted to 0 dB from +N dB gradually when the gain S2G of the signals S2 is updated with −N dB resulting from the AGC 14 updates gain of the PGA 10 with −N dB.

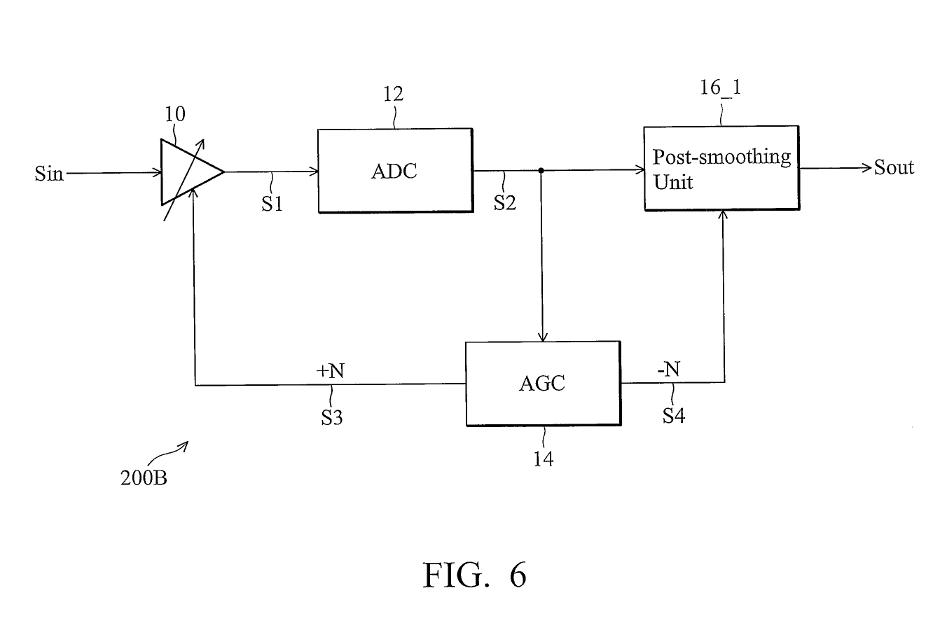

In some embodiments, as shown in FIG. 6, the AGC 14 may also generate the signals S3 and S4 to control the PGA 10 and the post-smoothing unit 16_1 according to the signals S2 (digital signals) generated by the ADC 12 rather than the signals S1 (analog signals) generated by the PGA 10 as shown in FIG. 4. The structure and operations of the electronic device 200B which are same as that in electronic device 200A are omitted for brevity.

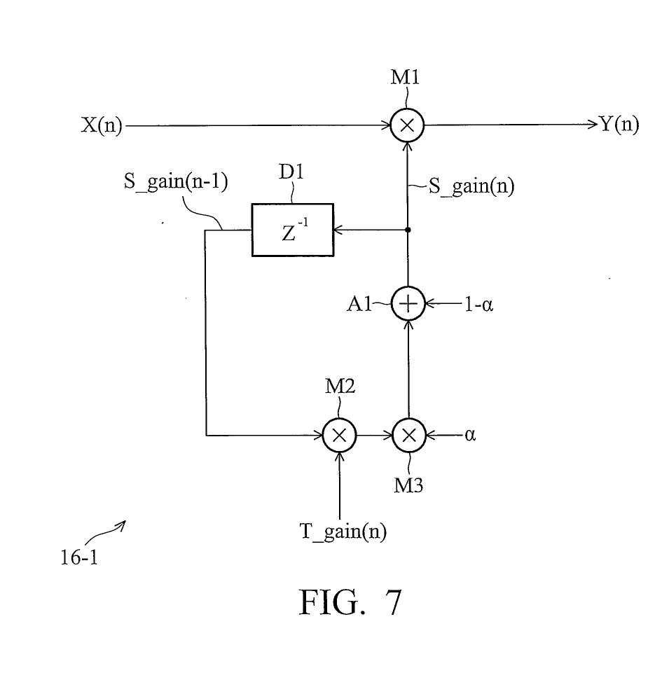

FIG. 7 shows an embodiment of a post-smoothing unit according to the invention. The post-smoothing unit 16_1 generates a smooth gain S_gain(n) to update the gain X(n) of the signals S2 from the ADC 12 according to an equation S_gain(n)=α×S_gain(n−1)×T_gain(n)+(1−α) when the AGC updates gains of PGA 10. In this case, S_gain(n) represents the smooth gain SMG shown in FIG. 5, T_gain(n) represents the gain of the signals S4 from the AGC 14, and al represents an adjusting factor between 0 and 1. Y(n) represents the gain of the output signal Sout as shown in FIG. 5 and can be obtained according to an equation Y(n)=X(n)×S_gain(n).

For example, when the AGC 14 updates the gain T_gain(n) of the signals S4 with +1 dB, the smooth gain S_gain (n) generated by the post-smoothing unit 16_1 can be adjusted to 0 dB from −1 dB gradually, such that the gain X(n) of the signals S2 from the ADC 12 can be smoothed. Alternatively, when the AGC 14 updates the gain T_gain(n) of the signals S4 with −1 dB, the smooth gain S_gain (n) generated by the post-smoothing unit 16_1 can be adjusted to 0 dB from +1 dB gradually, such that the gain X(n) of the signals S2 from the ADC 12 can be smoothed.

As shown, the post-smoothing unit 16_1 comprises multipliers M1˜M3, a delay unit D1 and an adder A1. The multiplier M1 multiplies the gain X(n) of the signal S2 from the ADC 12 by the smooth gain S_gain(n) from the adder A1. The delay unit D1 receives the smooth gain S_gain(n) from the adder A1 and outputs a delayed smooth gain S_gain(n−1) to the multiplier M2. The multiplier M2 receives the gain T_gain(n) of the signals S4 from the AGC 14, and multiplies the gain T_gain(n) of the signals S4 by the delayed smooth gain S_gain(n−1) and outputs the multiplied gain to the multiplier M3. The multiplier M3 multiplies the multiplied gain from the multiplier M2 by the adjusting factor α and outputs a decayed gain to the adder A1. The adder A1 adds the decayed gain to (1−α) to generate the smooth gain S_gain (n).

For example, the smooth gain S_gain(n−1) is initially at 0 dB, the adjusting factor is 0.9. When the gain T_gain(n) of the signals S4 is updated with −1 dB (i.e., 0.76) by the AGC 14 at time tₐ, the smooth gain S_gain(n) is −0.9 dB+0.1 at time tₙ and then the smooth gain S_gain(n) is adjusted to 0 dB from −0.9 dB+0.1 gradually after time tₙ, It should be noted that the gain T_gain(n+1) of the signals S4 is updated with 0 dB at time tₐ₊₁, and when the smooth gain S_gain(n) is 0 dB, it means that the post-smoothing unit 16_1 stops updating the gain of the signals S2 from the ADC 12.

Because the gain Y(n) of the output signal Sout is obtained according to the equation Y(n)=X(n)×S_gain(n), when the gain X(n) of the signals S2 is updated with +1 dB, the multiplier M1 multiplies gain X(n) by the smooth gain S_gain(n−1), such that the gain Y(n) of the output signal Sout is gradually adjusted to +1 dB.

Conversely, when the gain T_gain(n) of the signals S4 is updated with +1 dB (i.e., 1.14) by the AGC 14 at time tₙ, the smooth gain S_gain(n) is 0.9 dB+0.1 at time tₙ and then smooth gain S_gain(n) is adjusted to 0 dB from 0.9 dB+0.1 gradually after time tₙ, It should be noted that the gain T_gain(n+1) of the signals S4 is updated with 0 dB at time tₙ₊₁, and when the smooth gain S_gain(n) is 0 dB, it means that the post-smoothing unit 16_1 stops updating the gain of the signals S2 from the ADC 12. Because the gain Y(n) of the output signals Sout is obtained according to the equation Y(n)=X(n)×S_gain(n), when the gain X(n) of the signals S2 is updated with −1 dB, the multiplier M1 multiplies gain X(n) with the smooth gain S_gain(n−1), such that the gain Y(n) of the output signals Sout is gradually adjusted to −1 dB.

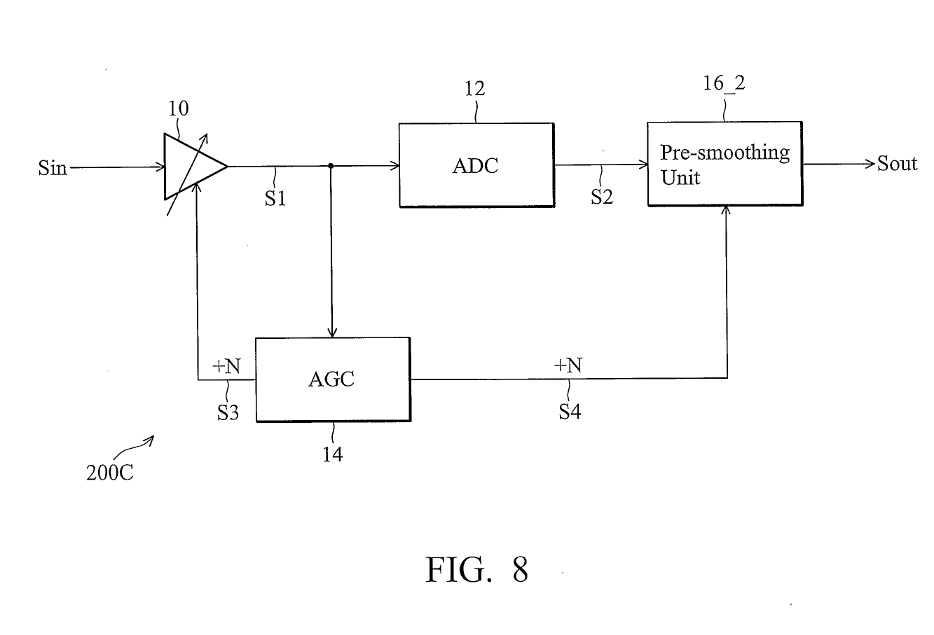

FIG. 8 shows an embodiment of an electronic device according to the invention. As shown, in the electronic device 200C, the pre-smoothing unit generates a smooth gain to adjust the signals S2 for a time period before the AGC updates gains of PGA 10, such that the gain change of the signals S2 (amplified by the PGA 10 and converted by the ADC 12) can be smoothed.

Before the AGC 14 generates the signals S3 to update the gain of the PGA 10 with +N dB according to signal strength of the signals S1, the AGC 14 also generates the signals S4 to enable the pre-smoothing unit 16_2 to update the gain of the signals S2 from ADC 12 during a time period before the gain of the PGA 10 changes, such that gain change of the output signal Sout can be smoothed.

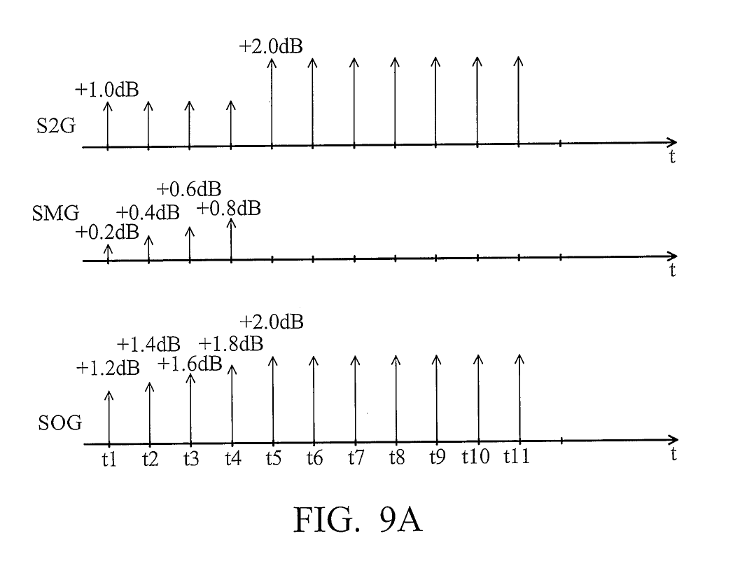

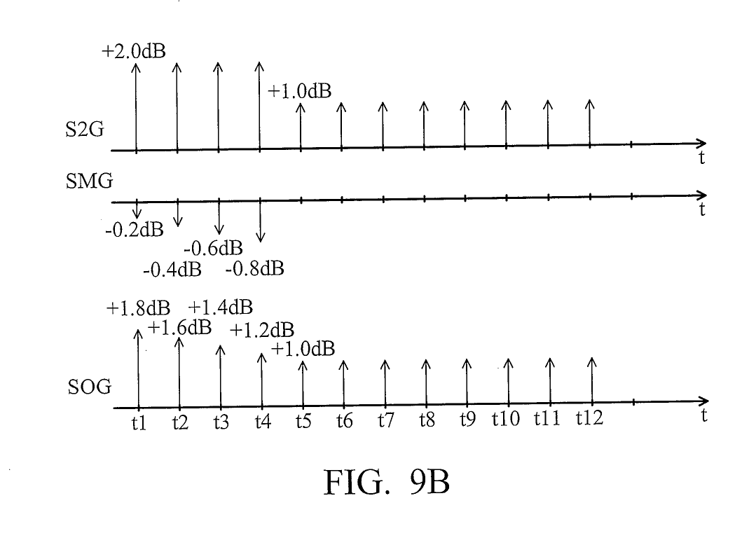

FIG. 9A shows a diagram illustrating gain smoothing of the signals from the ADC by the pre-smoothing unit according to an embodiment of the invention, in which S2G represents gain of the signals S2 from the ADC 12, SMG represents the smooth gain generated by the pre-smoothing unit 16_2 and the SOG represents gain of the output signals Sout. As shown, the gain S2G of the signals S2 is adjusted to +2 dB from +1 dB at time t5 as the AGC 14 updates gain of the PGA 10 with +1 dB at time t5. The pre-smoothing unit 16_2 generates the smooth gain SMG to update the gain of the signal S2 from ADC 12 during times t1˜t4, such that gain change of the output signal Sout can be smoothed.

For example, the pre-smoothing unit 16_2 generates the smooth gain SMG with +0.2 dB to update the gain S2G (i.e., +1.0 dB), such that the gain SOG of the output signal Sout is increased to +1.2 dB from +1.0 dB, at time t1. At time t2, the pre-smoothing unit 16_2 then generates the smooth gain SMG with +0.4 dB to adjust the gain S2G (i.e., +1.0 dB), such that the gain SOG is increased to +1.4 dB from +1.2 dB.

At time t3, the pre-smoothing unit 16_2 generates the smooth gain SMG with +0.6 dB to adjust the gain S2G (i.e., +1.0 dB), such that the gain SOG is increased to +1.6 dB from +1.4 dB. At time t4, the pre-smoothing unit 16_2 then generates the smooth gain SMG with +0.8 dB to adjust the gain S2G (i.e., +1.0 dB), such that the gain SOG is increased to +1.8 dB from +1.6 dB. Finally, after time t5, the pre-smoothing unit 16_2 generates the smooth gain SMG with 0 dB to adjust the gain S2G, i.e., the post-smoothing unit 16_1 stops adjusting the gain S2G of the signals S2. Then, the gain SOG of the output signals Sout is increased to +2.0 dB from +1.8 dB when the gain S2G of the signals S2 is increased to +2 dB from +1 dB and the AGC 14 updates gain of the PGA 10 with +1 dB at time t5.

In this case, the smooth gain generated by the pre-smoothing unit 16_2 is adjusted to 0.8 dB from 0 dB gradually during a time period, and is updated with 0 dB after the time period, but is not limited thereto. The smooth gain generated by the pre-smoothing unit 16_2 can also be adjusted to 0 dB from −N dB gradually during a time period, and is updated with 0 dB after the time period when the gain S2G of the signals S2 is updated with +N dB resulting from that the AGC 14 updates gain of the PGA 10 with +N dB.

When the AGC 14 generates the signals S3 to update the gain of the PGA 10 with −N dB according to signal strength of the signals S1, the AGC 14 also generates the signals S4 to enable the pre-smoothing unit 16_2 to decrease the gain of the signals S2 from ADC 12 during a time period before the gain of the PGA 10 changes, such that gain change of the output signals Sout can be smoothed.

FIG. 9B shows a diagram illustrating gain smoothing of the signals from the ADC by the pre-smoothing unit according to an embodiment of the invention. As shown, the gain S2G of the signals S2 is adjusted to +1 dB from +2 dB at time t5 as the AGC 14 updates gain of the PGA 10 with −1 dB at time t5. The pre-smoothing unit 16_2 generates the smooth gain SMG to update the gain of the signals S2 from ADC 12 during times t1˜t4, such that gain change of the output signals Sout can be smoothed.

At time t1, the pre-smoothing unit 16_2 generates the smooth gain SMG with −0.2 dB to adjust the gain S2G of +2.0 dB, such that the gain SOG of the output signals Sout is only decreased to +1.8 dB rather than +2.0 dB. At time t2, the pre-smoothing unit 16_2 then generates the smooth gain SMG with −0.4 dB to adjust the gain S2G of +2.0 dB, such that the gain SOG is decreased to +1.6 dB rather than +2.0 dB or +1.8 dB.

At time t3, the pre-smoothing unit 16_2 generates the smooth gain SMG with −0.6 dB to adjust the gain S2G of +2.0 dB, such that the gain SOG is decreased to +1.4 dB rather than +2.0 dB or +1.6 dB. At time t4, the pre-smoothing unit 16_2 then generates the smooth gain SMG with −0.8 dB to adjust the gain S2G of +2.0 dB, such that the gain SOG is decreased to +1.2 dB from +1.4 dB. Finally, after time t5, the pre-smoothing unit 16_2 generates the smooth gain SMG with 0 dB to adjust the gain S2G, i.e., the pre-smoothing unit 16_1 stops adjusting the gain S2G of the signals S2. Then, the gain SOG of the output signals Sout is decreased to +1.0 dB from +1.2 dB because the gain S2G of the signals S2 is adjusted to +1.0 dB from +2.0 dB at time t5 resulting from the AGC 14 updates gain of the PGA 10 with −1 dB at time t5.

In this case, the smooth gain generated by the pre-smoothing unit 16_2 is adjusted to −0.8 dB from 0 dB gradually during a time period and is updated with 0 dB after the time period, but is not limited thereto. The smooth gain generated by the pre-smoothing unit 16_2 can also be adjusted to 0 dB from −N dB gradually during a time period, and is updated with 0 dB after the time period when the gain S2G of the signal S2 is updated with −N dB resulting from that the AGC 14 updates gain of the PGA 10 with −N dB.

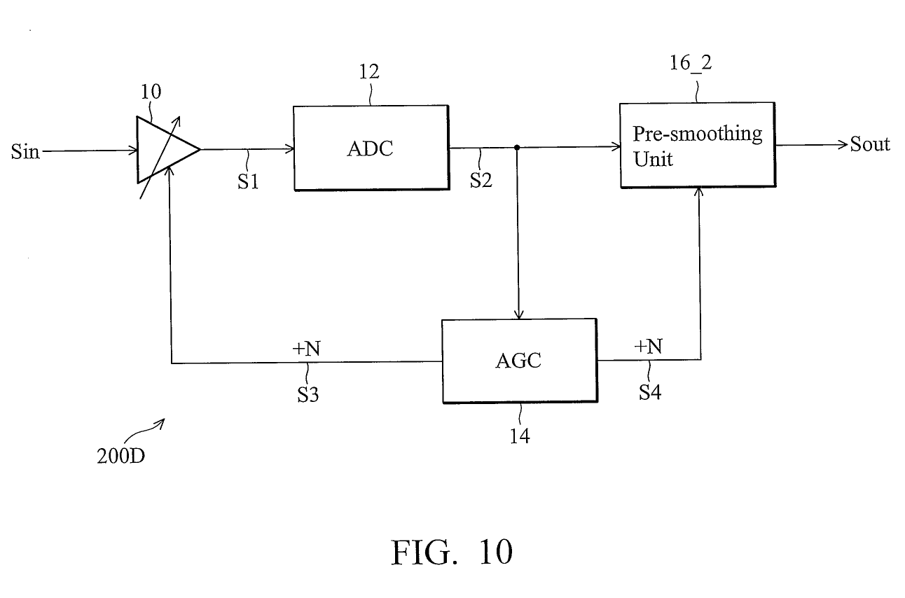

In some embodiments, as shown in FIG. 10, the AGC 14 can also generate the signals S3 and S4 to control the PGA 10 and the pre-smoothing unit 16_2 according to the signals S2 (digital signals) generated by the ADC 12 rather than the signals S1 (analog signals) generated by the PGA 10 as shown in FIG. 8. The structure and operations of the electronic device 200D which are same as that in electronic device 200C are omitted for brevity.

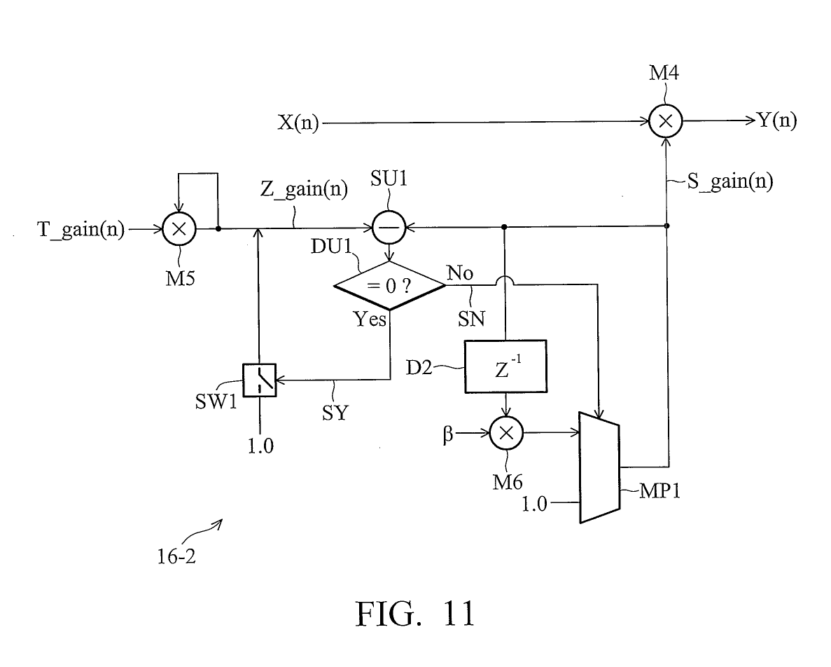

FIG. 11 shows an embodiment of a pre-smoothing unit according to the invention. The pre-smoothing unit 16_2 generates a smooth gain S_gain(n) to update the gain X(n) of the signals S2 from the ADC 12 before the AGC updates gain of the PGA 10, in which the smooth gain S_gain(n) can be regarded as the smooth gain SMG as shown in FIG. 5.

When the smooth gain S_gain(n) is not equal to the gain T_gain(n) of the signals S4 provided by the AGC 14, the pre-smoothing unit 16_2 generates the smooth gain S_gain(n) according to an equation S_gain(n)=β×S_gain(n−1), in which β represents an adjusting factor. For example, the adjusting factor β can be 0.1×N dB if the AGC 14 updates the PGA 12 with +N dB, or can be 0.1×(−N)dB if the AGC 14 updates the PGA 12 with −N dB. Y(n) represents the gain of the output signals Sout as shown in FIG. 5 and can be obtained according to an equation Y(n)=X(n)×S_gain(n). The gain Z_gain(n) can be obtained according to an equation Z_gain(n)=Z_gain(n−1)×T_gain(n), holding the gain T_gain(n) originally provided by the AGC 14 during gain smoothing. Details of T_gain holding is described below. For example, the gain T_gain is initially set to 1 (e.g. 0 dB) at time t0, resulting in the gain Z_gain is set to 1. As gain change at time t1, the gain T_gain is set to +N dB or (−N)dB provided by the AGC 14, as a result, the Z_gain(n) is set to +N dB or (−N)dB. After the time t1, the gain T_gain is set to 1 (e.g. 0 dB), resulting in the gain Z_gain maintains (i.e. +N dB or (−N)dB) until the gain S_gain is adjusted to reach the gain Z_gain. After the gain S_gain is adjusted to reach the gain Z_gain, the gain Z_gain is set to 1 (e.g. 0 dB) to regain the initial state.

When the AGC 14 updates the gain T_gain(n) of the signals S4 with +1.0 dB, the gain Z_gain(n) is +1.0 dB calculated by the equation Z_gain(n)=T_gain(n)×Z_gain(n−1). As described above, the gain Z_gain(n) is still maintained at +1.0 dB when the gain T_gain(n+1) is updated with 0 dB by the AGC 14. When the smooth gain S_gain(n) does not reach +1.0 dB (i.e. the gain T_gain(n)) provided by the AGC 14, the smooth gain S_gain(n) generated by the pre-smoothing unit 16_2 can be adjusted to +1.0 dB from 0 dB gradually, such that the gain X(n) of the signals S2 from the ADC 12 can be smoothed.

When the AGC 14 updates the gain T_gain(n) of the signals S4 with −1.0 dB, the gain Z_gain(n) is set to −1.0 dB calculated by the equation Z_gain(n)=T_gain(n)×Z_gain(n−1). As described above, the gain Z_gain(n) is still maintained at −1.0 dB when the gain T_gain(n+1) is updated with 0 dB by the AGC 14. When the smooth gain S_gain(n) does not reach −1.0 dB (i.e. the gain T_gain(n)) provided by the AGC 14, the smooth gain S_gain (n) generated by the pre-smoothing unit 16_2 can be adjusted to −1.0 dB from 0 dB gradually, such that the gain X(n) of the signals S2 from the ADC 12 can be smoothed.

When the smooth gain S_gain(n) is equal to the gain Z_gain(n), the smooth gain S_gain(n) and the gain Z_gain(n) are both updated to 0 dB, i.e., the pre-smoothing unit 16_2 generates the smooth gain S_gain(n) with 0 dB to update the gain X(n) of the signals S2 from the ADC 12. Namely, the pre-smoothing unit 16_2 stops updating the gain X(n) of the signals S2 from the ADC 12.

As shown, the pre-smoothing unit 16_2 comprises multipliers M4˜M6, a subtractor SU1, a determining unit DU1, a switching unit SW1, a delay unit D2 and a multiplexer MP1. The multiplier M4 multiplies the gain X(n) of the signals S2 from the ADC 12 by the smooth gain S_gain(n) from the multiplexer MP1. The multiplier M5 stores the gain T_gain(n) of the signals S4 updated by the AGC 14 to serve as the gain Z_gain(n) until the smooth gain S_gain(n) is equal to the gain Z_gain(n). The subtractor SU1 subtracts the gain Z_gain(n) from the smooth gain S_gain(n) and outputs the subtracted result to the determining unit DU1. The determining unit DU1 determines whether the smooth gain S_gain(n) is equal to the gain Z_gain(n) according to the subtracted result and outputs two signals SY and SN according to the determined results.

As the subtracted result is not zero, i.e., the smooth gain S_gain(n) is not equal to the gain Z_gain(n), the determining unit DU1 outputs the signal SN with a high logic level and the signal SY with a low logic level. Because the signal SY is at the low logic level, the switching unit SW1 does not output a gain with 0 dB (i.e., 1.0 ) to reset the gain Z_gain(n). Because the signal SN is at the high logic level, the multiplexer MP1 outputs the result of the multiplier M6 to serve as the smooth gain S_gain(n). At this time, i.e., the smooth gain S_gain(n) is not equal to the gain Z_gain(n), the multiplier M6 multiplies the adjusting factor α by a previous smooth gain S_gain(n−1) and outputs the multiplied result to the multiplexer MP1. The multiplexer MP1 outputs the multiplied result, i.e., the previous smooth gain S_gain(n−1) multiplied by the adjusting factor A, to serve as the smooth gain S_gain(n).

When the subtracted result is zero, it means that the smooth gain S_gain(n) is equal to the gain Z_gain(n), and then the determining unit DU1 outputs the signal SN with a low logic level and the signal SY with a high logic level. Because the signal SY is at the high logic level, the switching unit SW1 is turned on to output a gain with 0 dB (i.e., 1.0 ) to update the gain Z_gain(n). In addition, because the signal SN is at the low logic level, the multiplexer MP1 outputs a gain with 0 dB (i.e., 1.0) to serve as the smooth gain S_gain(n). Then, the multiplier M4 multiplies the gain X(n) of the signals S2 from the ADC 12 by the smooth gain S_gain(n) of 0 dB from the multiplexer MP1. Namely, the pre-smoothing unit 16_2 stops updating the gain X(n) of the signal S2 from the ADC 12.

For example, the smooth gain S_gain(n) is initially at 0 dB, the adjusting factor β is 0.1 dB if the AGC 14 updates the PGA 12 with +1.0 dB. When the gain T_gain(n) of the signals S4 is updated with +1.0 dB (i.e., 1.14) by the AGC 14 at time tₙ, the multiplier M5 stores the gain T_gain(n) (i.e. +1.0 dB) to serve as the gain Z_gain(n). The subtractor SU1 subtracts the gain Z_gain(n) (i.e. +1.0 dB) from the smooth gain S_gain(n) and outputs the subtracted result to the determining unit DU1. The determining unit DU1 determines that the smooth gain S_gain(n) is not equal to the gain Z_gain(n) according to the subtracted result and outputs the signal SN with a high logic level and the signal SY with a low logic level. Hence, the switching unit SW1 does not output a gain with 0 dB to update the gain Z_gain(n) and the multiplexer MP1 outputs the result of the multiplier M6 to serve as the smooth gain S_gain(n). The multiplier M6 multiplies the adjusting factor β (i.e., +0.1 dB) by a previous smooth gain S_gain(n−1) (i.e., 0 dB) and outputs the multiplied result with +0.1 dB to the multiplexer MP1. The multiplexer MP1 outputs the multiplied result with +0.1 dB serving as the smooth gain S_gain(n).

Because the current smooth gain S_gain(n) with +0.1 dB is not equal to the gain T_gain(n) with +1.0 dB, the determining unit DU1 outputs the signal SN with the high logic level and the signal SY with the low logic level again. The multiplier M6 multiplies the adjusting factor β (i.e., +0.1 dB) by the previous smooth gain S_gain(n−1) with +0.1 dB and outputs the multiplied result with +0.2 dB to the multiplexer MP1. The multiplexer MP1 outputs the multiplied result with +0.2 dB serving as the smooth gain S_gain(n). Similarly, because the current smooth gain S_gain(n) with +0.2 dB is not equal to the gain T_gain(n) with +1.0 dB, the determining unit DU1 outputs the signal SN with the high logic level and the signal SY with the low logic level again. The multiplier M6 multiplies the adjusting factor β (i.e., +0.1 dB) by the previous smooth gain S_gain(n−1) with +0.2 dB and outputs the multiplied result with +0.3 dB to the multiplexer MP1. The multiplexer MP1 outputs the multiplied result with +0.3 dB serving as the smooth gain S_gain(n). And so on, the delay unit D2, the multiplier M6 and the multiplexer MP1 updates the smooth gain S_gain(n) by the adjusting factor β (i.e., +0.1 dB) over and over, until the smooth gain S_gain(n) is equal to the gain Z_gain(n).

When the smooth gain S_gain(n) reaches (or equals) the gain Z_gain(n), the determining unit DU1 outputs the signal SN with a low logic level and the signal SY with a high logic level. Because the signal SY is at the high logic level, the switching unit SW1 is turned on to output a gain with 0 dB (i.e., 1.0) to update the gain Z_gain(n). In addition, because the signal SN is at the low logic level, the multiplexer MP1 outputs a gain with 0 dB (i.e., 1.0) to serve as the smooth gain S_gain(n). Then, the multiplier M4 multiplies the gain X(n) of the signal S2 from the ADC 12 by the smooth gain S_gain(n) of 0 dB from the multiplexer MP1. Namely, the pre-smoothing unit 16_2 stops updating the gain X(n) of the signals S2 from the ADC 12.

Alternatively, the adjusting factor β is −0.1 dB if the AGC 14 updates the PGA 12 with −1.0 dB. When the gain T_gain(n) of the signal S4 is updated with −1 dB (i.e., 0.76) by the AGC 14, the multiplier M5 stores the gain T_gain(n) (i.e. −1.0 dB) to serve as the gain Z_gain(n). The subtractor SU1 subtracts the gain Z_gain(n) (i.e. −1.0 dB) from the smooth gain S_gain(n) and outputs the subtracted result to the determining unit DU1. The determining unit DU1 determines that the smooth gain S_gain(n) is not equal to the gain Z_gain(n) according to the subtracted result and outputs the signal SN with a high logic level and the signal SY with a low logic level. Hence, the switching unit SW1 does not output a gain with 0 dB to reset the gain Z_gain(n) and the multiplexer MP1 outputs the result of the multiplier M6 to serve as the smooth gain S_gain(n). The multiplier M6 multiplies the adjusting factor β (i.e., −0.1 dB) by a previous smooth gain S_gain(n−1) (i.e., 0 dB) and outputs the multiplied result with −0.1 dB to the multiplexer MP1. The multiplexer MP1 outputs the multiplied result with −0.1 dB serving as the smooth gain S_gain(n).

Because the current smooth gain S_gain(n) with −0.1 dB is not equal to the gain T_gain(n) with −1.0 dB, the determining unit DU1 outputs the signal SN with the high logic level and the signal SY with the low logic level again. The multiplier M6 multiplies the adjusting factor β (i.e., −0.1 dB) by the previous smooth gain S_gain(n−1) with −0.1 dB and outputs the multiplied result with −0.2 dB to the multiplexer MP1. The multiplexer MP1 outputs the multiplied result with −0.2 dB serving as the smooth gain S_gain(n). Similarly, because the current smooth gain S_gain(n) with −0.2 dB is not equal to the gain T_gain(n) with −1.0 dB, the determining unit DU1 outputs the signal SN with the high logic level and the signal SY with the low logic level again. The multiplier M6 multiplies the adjusting factor β (i.e., −0.1 dB) by the previous smooth gain S_gain(n−1) with −0.2 dB and outputs the multiplied result with −0.3 dB to the multiplexer MP1. The multiplexer MP1 outputs the multiplied result with −0.3 dB serving as the smooth gain S_gain(n). And so on, the delay unit D2, the multiplier M6 and the multiplexer MP1 update the smooth gain S_gain(n) with −0.1 dB over and over, until the smooth gain S_gain(n) is equal to the gain T_gain(n).

When the smooth gain S_gain(n) reaches (or equals) the gain T_gain(n), the determining unit DU1 outputs the signal SN with a low logic level and the signal SY with a high logic level. Because the signal SY is at the high logic level, the switching unit SW1 is turned on to output a gain with 0 dB (i.e., 1.0) to update the gain Z_gain(n). In addition, because the signal SN is at the low logic level, the multiplexer MP1 outputs a gain with 0 dB (i.e., 1.0) to serve as the smooth gain S_gain(n). Then, the multiplier M4 multiplies the gain X(n) of the signals S2 from the ADC 12 by the smooth gain S_gain(n) of 0 dB from the multiplexer MP1. Namely, the pre-smoothing unit 16_2 stops updating the gain X(n) of the signals S2 from the ADC 12.

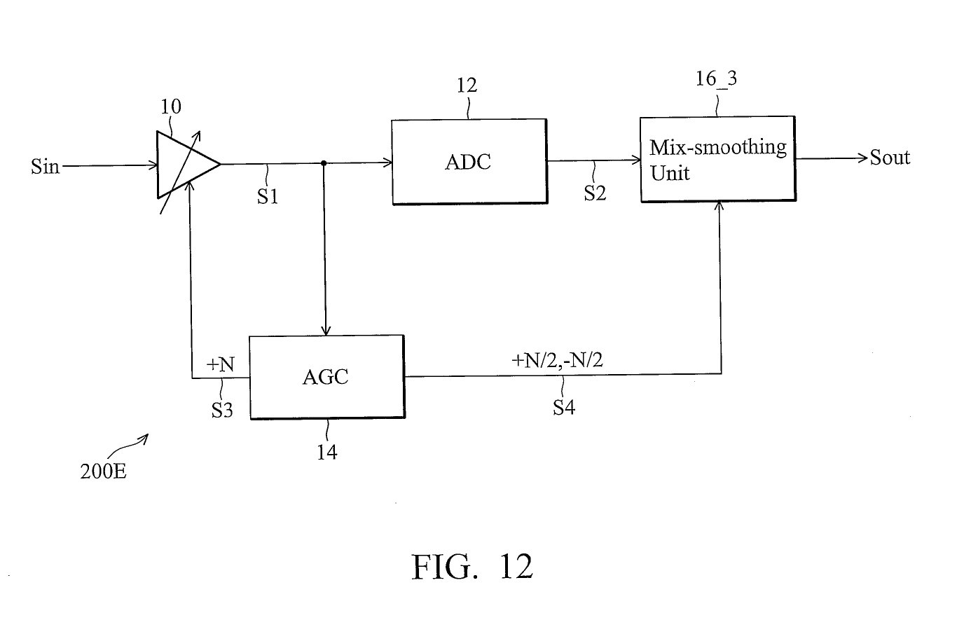

FIG. 12 shows an embodiment of an electronic device according to the invention. As shown, in the electronic device 200E, the mix-smoothing unit 16_3 generates a smooth gain to update the signals S2 during a time period comprising a moment of that the AGC updates gains PGA 10, such that the gain change of the signals S2 (amplified by the PGA 10 and converted by the ADC 12) can be smoothed.

Before the AGC 14 generates the signals S3 to update the gain of the PGA 10 with +N dB according to signal strength of the signals S1, the AGC 14 generates the signals S4 to enable the mix-smoothing unit 16_3 to update the gain of the signals S2 from ADC 12 during a first time period. After the AGC 14 generates the signal S3 to update the gain of the PGA 10 by +N dB, the AGC generates the signal S4 to enable the mix-smoothing unit 16_3 to update the gain of the signal S2 from ADC 12 during a second time period.

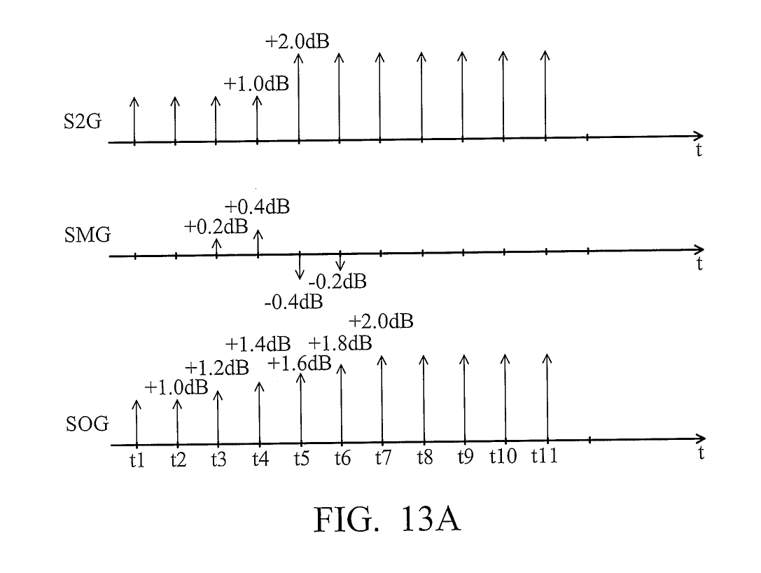

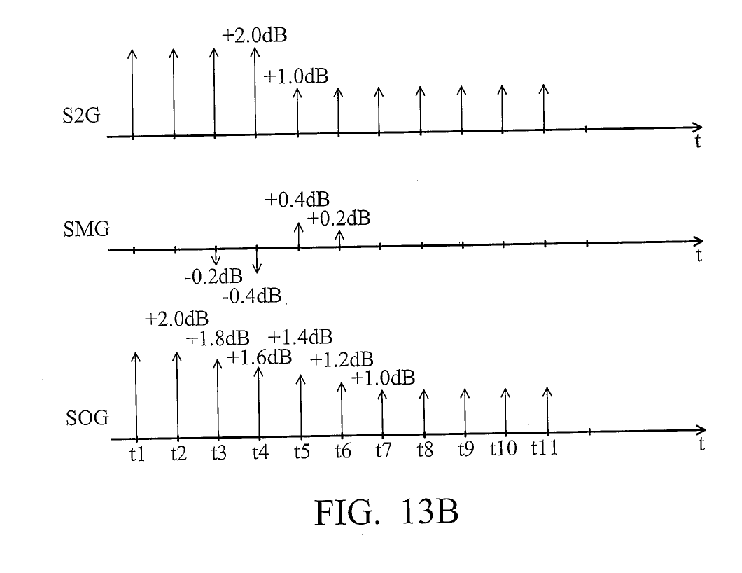

FIG. 13A shows a diagram illustrating gain smoothing of the signals from the ADC by the mix-smoothing unit according to an embodiment of the invention, in which S2G represents gain of the signals S2 from the ADC 12, SMG represents the smooth gain generated by the mix-smoothing unit 16_3 and the SOG represents gain of the output signals Sout. As shown, the gain S2G of the signals S2 is adjusted to +2 dB from +1 dB at time t5 as the AGC 14 updates gain of the PGA 10 by +1 dB at time t5. The mix-smoothing unit 16_3 generates the smooth gain SMG to update (increase) the gain of the signals S2 from ADC 12 during times t3 and t4 and to update (decrease) the gain of the signals S2 during times t5 and t6, such that gain change of the output signals Sout can be smoothed.

At time t3, the mix-smoothing unit 16_3 generates the smooth gain SMG with +0.2 dB to adjust the gain S2G (i.e., +1.0 dB), such that the gain SOG of the output signals Sout is increased to +1.2 dB from +1.0 dB. At time t4, the mix-smoothing unit 16_3 then generates the smooth gain SMG with +0.4 dB to adjust the gain S2G (i.e., +1.0 dB), such that the gain SOG is increased to +1.4 dB from +1.2 dB. At time t5, the mix-smoothing unit 16_3 generates the smooth gain SMG with −0.4 dB to adjust the gain S2G (i.e., +2 dB), such that the gain SOG of the output signals Sout is increased to +1.6 dB from +1.4 dB. At time t6, the mix-smoothing unit 16_3 then generates the smooth gain SMG with −0.2 dB to adjust the gain S2G (i.e., +2 dB), such that the gain SOG is increased to +1.8 dB from +1.6 dB.

Finally, after time t7, the mix-smoothing unit 16_3 generates the smooth gain SMG with 0 dB to adjust the gain S2G, i.e., the mix-smoothing unit 16_3 stops updating the gain S2G of the signals S2. Then, the gain SOG of the output signals Sout is increased to +2.0 dB from +1.8 dB because the gain S2G of the signals S2 is adjusted to +2.0 dB from +1.0 dB at time t5.

FIG. 13B shows a diagram illustrating gain smoothing of the signals from the ADC by the mix-smoothing unit according to an embodiment of the invention, in which S2G represents gain of the signals S2 from the ADC 12, SMG represents the smooth gain generated by the mix-smoothing unit 16_3 and the SOG represents gain of the output signals Sout.

As shown, the gain S2G of the signals S2 is adjusted to +1.0 dB from +2.0 dB at time t5 as the AGC 14 updates gain of the PGA 10 with −1 dB at time t5. The mix-smoothing unit 16_3 generates the smooth gain SMG to update (decrease) the gain of the signals S2 from ADC 12 during times t3 and t4 and to update (increase) the gain of the signals S2 during times t5 and t6, such that gain change of the output signal Sout can be smoothed.

At time t3, the mix-smoothing unit 16_3 generates the smooth gain SMG with −0.2 dB to adjust the gain S2G (i.e., +1.0 dB), such that the gain SOG of the output signals Sout is decreased to +1.8 dB from +2.0 dB. At time t4, the mix-smoothing unit 16_3 then generates the smooth gain SMG with −0.4 dB to adjust the gain S2G (i.e., +1.0 dB), such that the gain SOG is decreased to +1.6 dB from +1.8 dB. At time t5, the mix-smoothing unit 16_3 generates the smooth gain SMG with +0.4 dB to adjust the gain S2G (i.e., +2 dB), such that the gain SOG of the output signals Sout is decreased to +1.4 dB from +1.6 dB. At time t6, the mix-smoothing unit 16_3 then generates the smooth gain SMG with +0.2 dB to adjust the gain S2G (i.e., +2 dB), such that the gain SOG is increased to +1.2 dB from +1.4 dB.

Finally, after time t7, the mix-smoothing unit 16_3 generates the smooth gain SMG with 0 dB to adjust the gain S2G, i.e., the mix-smoothing unit 16_3 stops updating the gain S2G of the signals S2. Then, the gain SOG of the output signals Sout is decreased to +1.0 dB from +1.2 dB because the gain S2G of the signals S2 is updated to +1.0 dB from +2.0 dB at time t5.

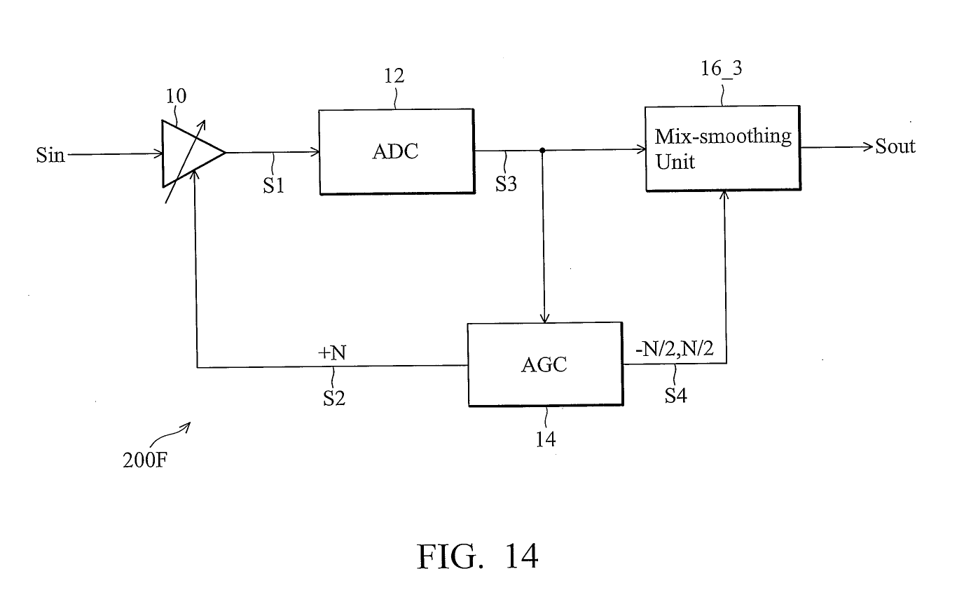

In some embodiments, as shown in FIG. 14, the AGC 14 can also generate the signals S3 and S4 to control the PGA 10 and the mix-smoothing unit 16_3 according to the signals S2 (digital signals) generated by the ADC 12 rather than the signals S1 (analog signals) generated by the PGA 10 as shown in FIG. 12. The structure and operations of the electronic device 200F which are same as that in electronic device 200E are omitted for brevity.

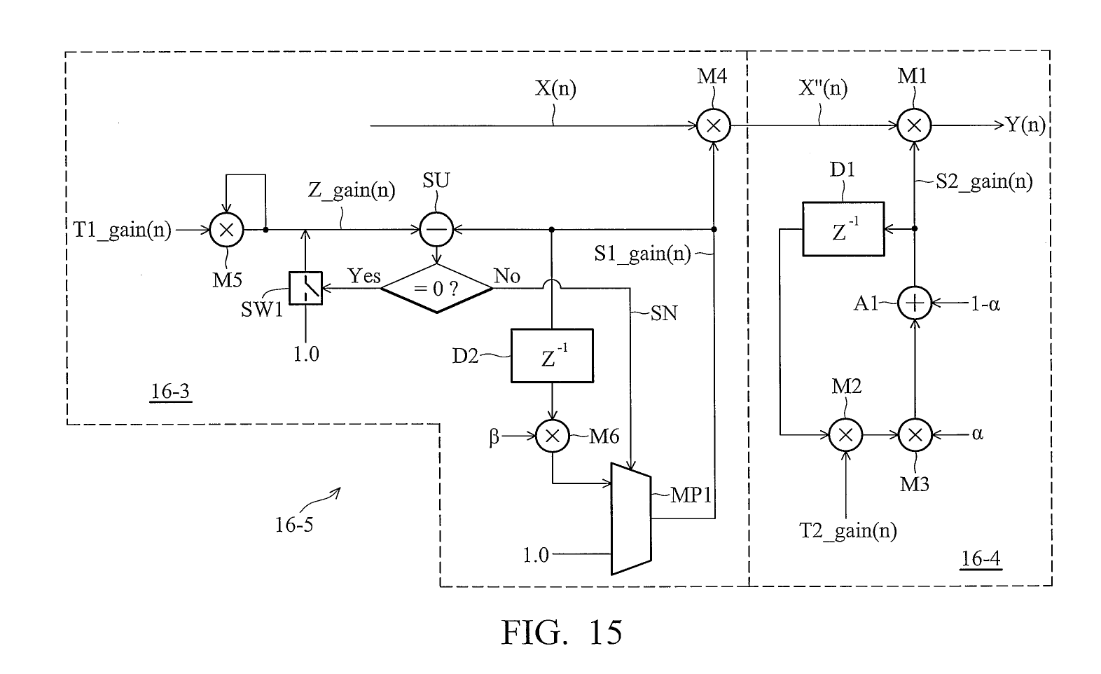

FIG. 15 shows an embodiment of the mix-smoothing unit according to the invention. As shown, the mix-smoothing unit 16_5 comprises a pre-smoothing unit 16_3 and a pre-smoothing unit 16_4. The mix-smoothing unit 16_5 generates a smooth gain (i.e., S1_gain(n) and S2_gain(n)) to update the gain X(n) of the signals S2 during a time period comprising a moment that the AGC 14 updates gain of the PGA 10, such that the gain change of the signals S2 (amplified by the PGA 10 and converted by the ADC 12) can be smoothed. The structure of the pre-smoothing unit 16_3 and the post-smoothing unit 16_4 is similar to that of the pre-smoothing unit 16_2 and the post-smoothing unit 16_1, and thus, detailed description of the structure thereof are omitted for brevity.

In the case where the gain of the PGA 10 is updated by +1 dB, the AGC 14 generates the signals S4 to enable the pre-smoothing unit 16_3 of the mix-smoothing unit 16_5 to gradually update the gain of the signals S2 with +0.5 dB in a first time period before the AGC 14 generates the signals S3 to update the gain of the PGA 10 with +1 dB according to signal strength of the signals S1. During the first time period, the post-smoothing 16_4 does not update the gain X(n) of the signals S2, i.e., the S2_gain(n) is 0 dB, and the gain Y(n) of the output signals Sout is equal to the gain X″(n) generated by the multiplier M4. Namely, the gain Y(n) of the output signals Sout can be obtained according to an equation Y(n)=X″(n)=X(n)×S1_gain(n).

Then, after the AGC 14 generates the signals S3 to update the gain of the PGA 10 by +1 dB, the AGC 14 generates the signals S4 to enable the post-smoothing unit 16_4 of the mix-smoothing unit 16_5 to update the gain of the signals S2 by −0.5 dB gradually. During the second time period, the pre-smoothing 16_3 does not update the gain X(n) of the signals S2, i.e., the S1_gain(n) is 0 dB, and the gain X(n) of the signals S2 is equal to the gain X″(n) generated by the multiplier M4. Namely, the gain Y(n) of the output signals Sout can be obtained according to an equation Y(n)=X″(n)×S2_gain(n)=X(n)×S2_gain(n).

For example, when the AGC 14 is going to update the PAG 10 by +1 dB, the AGC 14 may update the gain T1_gain(n) of the signals S4 by +0.5 dB in advance. Hence, the delay unit D2, the multiplier M6 and the multiplexer MP1 updates the smooth gain S1_gain(n) by the adjusting factor β (i.e., +0.1 dB), over and over during the first time period, until the smooth gain S1_gain(n) is equal to the gain T1_gain(n), i.e., +0.5 dB. Because of the equation Y(n)=X″(n)=X(n)×S1_gain(n), the gain Y(n) of the output signals Sout can be updated by the adjusting factor β (i.e., +0.1 dB) over and over until the smooth gain S1_gain(n) reaches +0.5 dB. When the smooth gain S1_gain(n) reaches (or equals) +0.5 dB (i.e., the gain T_gain(n)), the gain Z_gain(n) and the smooth gain S1_gain(n) are both updated with 0 dB. Namely, the pre-smoothing unit 16_3 stops updating the gain X(n) of the signals S2 from the ADC 12.

When the AGC 14 updates the PGA 10 by +1.0 dB, the AGC 14 also updates the gain T2_gain(n) of the signals S4 by −0.5 dB, such that the smooth gain S2_gain(n) is updated with 0 dB from −0.5 dB gradually. Because the gain Y(n) of the output signals Sout is obtained according to the equation Y(n)=X″(n)×S2_gain(n)=X(n)×S2_gain(n), as the smooth gain S2_gain(n) is updated to 0 dB from −0.5 dB gradually, the gain Y(n) of the output signals Sout is gradually adjusted to +1 dB from +0.5 dB. When the smooth gain S2_gain(n) is 0 dB, it means that the post-smoothing unit 16_4 stops updating the gain X(n) of the signals S2 from the ADC 12.

In a case where the gain of the PGA 10 is updated with −1 dB, the AGC 14 generates the signals S4 to enable the pre-smoothing unit 16_2 of the mix-smoothing unit 16_3 to update the gain of the signals S2 by −0.5 dB in a first time period before the AGC 14 generates the signals S3 to update the gain of the PGA 10 by −1 dB according to signal strength of the signals S1. During the first time period, the post-smoothing 16_4 does not update the gain X(n) of the signals S2, i.e., the S2_gain(n) is 0 dB, and the gain Y(n) of the output signals Sout is equal to the gain X″(n) generated by the multiplier M4. Namely, the gain Y(n) of the output signals Sout can be obtained according to an equation Y(n)=X″(n)=X(n)×S1_gain(n).

Then, after the AGC 14 generates the signals S3 to update the gain of the PGA 10 by −1 dB, the AGC 14 generates the signals S4 to enable the post-smoothing unit 16_4 of the mix-smoothing unit 16_3 to update the gain X(n) of the signals S2 with −0.5 dB. During the second time period, the pre-smoothing 16_3 does not update the gain X(n) of the signals S2, i.e., the S1_gain(n) is 0 dB, and the gain X(n) of the signals S2 is equal to the gain X″(n) generated by the multiplier M4. Namely, the gain Y(n) of the output signals Sout can be obtained according to an equation Y(n)=X″(n)×S2_gain(n)=X(n)×S2_gain(n).

For example, when the AGC 14 is going to update the PAG 10 by −1 dB, the AGC 14 may update the gain T1_gain(n) of the signals S4 to −0.5 dB in advance. Hence, the delay unit D2, the multiplier M6 and the multiplexer MP1 update the smooth gain Si_gain(n) with the adjusting factor β (i.e., −0.1 dB) over and over during the first time period, until the smooth gain S1_gain(n) is equal to the gain T1_gain(n), i.e., −0.5 dB. Because of the equation Y(n)=X″(n)=X(n)×S1_gain(n), the gain Y(n) of the output signals Sout can be updated with the adjusting factor β (i.e., −0.1 dB) over and over until the smooth gain S1_gain(n) reaches −0.5 dB. When the smooth gain S1_gain(n) reaches (or equals) −0.5 dB (i.e., the gain T_gain(n)), the gain Z_gain(n) and the smooth gain S1_gain(n) are both updated with 0 dB. Namely, the pre-smoothing unit 16_3 stops updating the gain X(n) of the signals S2 from the ADC 12.

When the AGC 14 updates the PGA 10 with −1.0 dB, the AGC 14 also updates the gain T2_gain(n) of the signals S4 with +0.5 dB, such that the smooth gain S2_gain(n) is adjusted to 0 dB from +0.5 dB gradually. Because the gain Y(n) of the output signals Sout is obtained according to the equation Y(n)=X″(n)×S2_gain(n)=X(n)×S2_gain(n), as the smooth gain S2_gain(n) is adjusted to 0 dB from +0.5 dB gradually, the gain Y(n) of the output signals Sout is gradually adjusted to −1 dB from −0.5 dB. Namely, when the smooth gain S2_gain(n) is 0 dB, the post-smoothing unit 16_4 stops updating the gain X(n) of the signals S2 from the ADC 12.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device, comprising:
an amplifier amplifying an input signal and generating an amplified signal;
an analog-to-digital converter (ADC) converting the amplified signal to a digital signal;
an automatic gain controller (AGC) updating a gain of the amplifier according to a strength of the amplified signal or amplified digital signal; and
a smoothing unit updating a gain of the digital signal from the ADC before and/or after the AGC updates the gain of the amplifier, such that unwanted sound caused when the AGC updates the gain of the amplifier is eliminated.

2. The electronic device as claimed in claim 1, wherein the smoothing unit generates a series of smooth gains to update the gain of the digital signal gradually before the AGC updates the gain of the amplifier by M dB, in which the smooth gains are increased to M dB from 0 dB and then updated with 0 dB.

3. The electronic device as claimed in claim 1, wherein the smoothing unit generates a series of smooth gains to update the gain of the digital signal gradually before the AGC updates the gain of the amplifier by −M dB, in which the smooth gains are decreased to −M dB from 0 dB and then updated with 0 dB.

4. The electronic device as claimed in claim 1, wherein the AGC updates a first expect gain to the smoothing unit before updating the amplifier, such that the smoothing unit generates a series of smooth gains to update the gain of the digital signal according to a first equation, detects whether each smooth gain is equal to the first expect gain, and stops updating the gain of the digital signal when the smooth gain is substantially equal to the first expect gain.

5. The electronic device as claimed in claim 4, wherein the first equation is S_gain(n)=β×S_gain(n−1), in which S_gain(n) represents the current smooth gain, S_gain(n−1) represents the previous smooth gain, and β represents a first adjusting factor.

6. The electronic device as claimed in claim 1, wherein the smoothing unit generates a series of smooth gains to update the gain of the digital signal gradually after the AGC updates the gain of the amplifier by M dB, in which the smooth gain is increased to 0 dB from −M dB.

7. The electronic device as claimed in claim 1, wherein the smoothing unit generates a series of smooth gains to update the gain of the digital signal gradually after the AGC updates the gain of the amplifier by −M dB, in which the smooth gains are decreased to 0 dB from M dB.

8. The electronic device as claimed in claim 1, wherein the AGC updates a second expect gain to the smoothing unit after updating the amplifier, such that the smoothing unit generates a series of smooth gains to update the gain of the digital signal according to a second equation S_gain(n)=α×S_gain(n−1)×T_gain(n)+(1+α), in which S_gain(n) represents the current smooth gain, S_gain(n−1) represents the previous smooth gain, T_gain(n) represents the second expect gain, and α represents a second adjusting factor between 0 and 1.

9. The electronic device as claimed in claim 1, wherein the smoothing unit generates a series of smooth gains to update the gain of the digital signal gradually during a first time period before the AGC updates the gain of the amplifier with M dB, in which the smooth gains are increased to
$$\frac{M}{2} dB$$
from 0 dB and then updated with 0 dB during the first time period, and then, the smoothing unit generates a series of smooth gains to update the gain of the digital signal gradually during a second time period after the AGC updates the gain of the amplifier with M dB, in which the smooth gains are decreased to 0 dB from
$$- \frac{M}{2} dB$$
during the second time period.

10. The electronic device as claimed in claim 1, wherein the smoothing unit generates a series of smooth gains to update the gain of the digital signal gradually during a first time period, before the AGC updates the gain of the amplifier with −M dB, in which the smooth gains are decreased to
$$- \frac{M}{2} dB$$
from 0 dB and then updated with 0 dB during the first time period, and then, after the AGC updates the gain of the amplifier with −M dB, and then, the smoothing unit generates a series of smooth gains to update the gain of the digital signal gradually during a second time period, in which the smooth gains are increased to 0 dB from
$$\frac{M}{2} dB$$
during the second time period.

11. The electronic device as claimed in claim 1, wherein the AGC updates a first expect gain to the smoothing unit before updating the amplifier, such that the smoothing unit generates a series of smooth gains to update the gain of the digital signal according to a first equation, detects whether each smooth gain is equal to the first expect gain, and stops updating the gain of the digital signal when the smooth gain is equal to the first expect gain, and the AGC updates a second expect gain to the smoothing unit after updating the amplifier, such that the smoothing unit generates a series of smooth gains to update the gain of the digital signal according to a second equation.

12. The electronic device as claimed in claim 11, wherein the first equation is S_gain(n)=β×S_gain(n−1), in which S_gain(n) represents the current smooth gain, S_gain(n−1) represents the previous smooth gain, and β represents a first adjusting factor.

13. The electronic device as claimed in claim 12, wherein the second equation is S_gain(n)=α×S_gain(n−1)×T_gain(n)+(1+α), in which S_gain(n) represents the current smooth gain, S_gain(n−1) represents the previous smooth gain, T_gain(n) represents the second expect gain, and a represents a second adjusting factor between 0 and 1.

14. A method for preventing unwanted sound caused by gain changes, comprising:
amplifying an input signal by an amplifier;
converting the amplified input signal to a digital signal;
updating a gain of the amplifier according to a strength of the amplified signal or amplified digital signal; and
updating a gain of the digital signal before and/or after updating the gain of the amplifier.

15. The method as claimed in claim 14, further comprising:
updating a first expect gain to a smoothing unit before updating the amplifier;
generating a series of smooth gains to update the gain of the digital signal according to a first equation;
detecting whether each smooth gain is equal to the first expect gain; and
stopping the update of the gain of the amplifier when the smooth gain is substantially equal to the first expect gain.

16. The method as claimed in claim 15, wherein the first equation is S_gain(n)=β×S_gain(n−1), in which S_gain(n) represents the current smooth gain, S_gain(n−1) represents the previous smooth gain, and β represents a first adjusting factor.

17. The method as claimed in claim 14, further comprising generating a series of smooth gains to update the gain of the digital signal gradually before updating the gain of the amplifier with M dB, in which the smooth gains are increased to M dB from 0 dB and then updated with 0 dB.

18. The method as claimed in claim 14, further comprising generating a series of smooth gains to update the gain of the digital signal gradually before updating the gain of the amplifier with −M dB, in which the smooth gains are decreased to −M dB from 0 dB and then updated with 0 dB.

19. The method as claimed in claim 14, further comprising generating a series of smooth gains to update the gain of the digital signal gradually after updating the gain of the amplifier with M dB, in which the smooth gains are increased to 0 dB from −M dB.

20. The method as claimed in claim 14, further comprising generating a smooth gain to update the gain of the digital signal gradually after updating the gain of the amplifier with −M dB, in which the smooth gain is decreased to 0 dB from M dB.

21. The method as claimed in claim 14, further comprising:
updating a second expect gain to the smoothing unit after updating the amplifier; and
generating a series of smooth gains to update the gain of the digital signal according to a second equation S_gain(n)=α×S_gain(n−1)×T_gain(n)+(1+α), in which S_gain(n) represents the current smooth gain, S_gain(n−1) represents the previous smooth gain, T_gain(n) represents the second expect gain, and α represents a second adjusting factor between 0 and 1.

22. The method as claimed in claim 14, further comprising:
generating a series of smooth gains to update the gain of the digital signal gradually during a first time period before updating the gain of the amplifier with −M dB, in which the smooth gains are decreased to
$$- \frac{M}{2} dB$$
from 0 dB and then updated with 0 dB during the first time period; and
generating a series of smooth gains to update the gain of the digital signal gradually during a second time period after updating the gain of the amplifier with −M dB, in which the smooth gain is increased to 0 dB from
$$\frac{M}{2} dB$$
during the second time period.

23. The method as claimed in claim 14, further comprising:
generating a series of smooth gains to update the gain of the digital signal gradually during a first time period before updating the gain of the amplifier with M dB, in which the smooth gains are increased to
$$\frac{M}{2} dB$$
from 0 dB and then updated with 0 dB; and
generating a series of smooth gains to update the gain of the digital signal gradually during a second time period after updating the gain of the amplifier with M dB, in which the smooth gains are decreased to 0 dB from
$$- \frac{M}{2} dB$$
during the second time period.
